(19) United States
(12) Patent Application Publication
(10) Pub. No.: US 2009/0135105 A1
(43) Pub. Date: May 28, 2009

(54) LIGHT-EMITTING ELEMENT AND DISPLAY APPARATUS USING THE SAME

(75) Inventors: Kenji Nakamura, Saitama (JP); Takuya Hata, Saitama (JP); Atsushi Yoshizawa, Saitama (JP)

Correspondence Address: DRINKER BIDDLE & REATH (DC), 1500 K STREET, N.W., SUITE 1100, WASHINGTON, DC, 20005-1209, US

(73) Assignee: Pioneer Corporation, Meguro-ku (JP)

(21) Appl. No.: 12/090,013

(22) PCT Filed: Oct. 12, 2006
(86) PCT No.: PCT/JP2006/320795

§ 371 Date: Aug. 11, 2008

(30) Foreign Application Priority Data
Oct. 14, 2005 (JP) 2005-300595

(51) Int. Cl. H01L 51/50; G09G 3/32

(52) U.S. Cl. 345/76; 313/504

(57) ABSTRACT

A light-emitting element comprises an auxiliary electrode provided on a substrate; an insulating layer provided on the auxiliary electrode; a first electrode supported by the insulating layer; a carrier injection layer made of an organic conductive material having carrier injecting property, and making contact with the first electrode; a light emission layer supported by the carrier injection layer; and a second electrode supported by the light emission layer, and a carrier dispersion layer having lower resistance than the carrier injection layer is provided between the carrier injection layer and the light emission layer. With this arrangement, a light-emitting element having good light emission characteristics in-a pixel is provided.

### TECHNICAL FIELD

The present invention relates to a light-emitting element including an organic thin film having carrier (hole or electron)-dispersing property and a display apparatus using the same.

### BACKGROUND ART

A light-emitting element for emitting light upon application of electric voltage is known which uses, for example, electroluminescence (hereinafter simply referred to as an EL) caused by recoupling of carriers (holes and electrons) of substances. For example, an EL display apparatus equipped with a display panel of injection-type organic EL elements using organic compound material has been developed. The organic EL elements include a red EL element configured to emit a red-colored light, a green EL element configured to emit a green-colored light, and a blue EL element configured to emit a blue-colored light. Arrangement of a plurality of pixel light-emitting units, each consisting of three organic EL elements respectively emitting red, green and blue colors (RGB), into a matrix pattern on a panel achieves a color display apparatus. With regard to a drive method for such display panel having the color display apparatus, a passive matrix drive type and an active matrix drive type are known. An EL display apparatus of an active matrix drive type is advantageous in that it has lower power consumption, and lower cross-talk between pixels as compared with that of a passive matrix type, and it is especially suitable for a display apparatus with large-screen and a high-definition.

The display panel of an active matrix drive EL display apparatus comprises anode power supply lines, cathode power supply lines, scanning lines for performing horizontal scanning, and data lines arranged to intersect with the scanning lines so as to provide a lattice pattern. RGB sub-pixels are formed at respective RGB intersections between the scanning lines and the data lines.

Each of the sub-pixels is provided with a field effect transistor (FET) for selecting the scanning line. A gate of the FET is connected to a scanning line. A drain of the FET is connected to a data line. A source of the FET is connected to a gate of another FET for driving light emission. A drive voltage is applied to a source of such light emission driving FET via the anode power supply line, and an anode end of the EL element is connected to a drain of the light emission driving FET. A capacitor is connected between the gate and the source of the light emission driving FET. Moreover, a ground potential is applied via the cathode power supply line to the cathode end of the EL element.

A conventional organic light emitting element, of which an organic EL element is a typical example, is an active element which essentially exhibits diode characteristics, and most of the organic light emitting elements produced so far have been driven by the passive matrix. In the passive matrix drive method, high luminosity is instantaneously required in order to perform line by line sequential driving, and since there is a limit to the number of scanning lines, it has been difficult to obtain a high-definition display apparatus.

Organic EL display apparatuses provided with TFT devices using polysilicon or the like have been investigated, which however have various drawbacks such as higher processing temperature, higher manufacturing cost per unit surface area making it unsuitable for a large screen, and necessity to provide at least two transistors and capacitors in each pixel causing reduced aperture ratio which necessitates emission of the organic EL elements with high luminosity.

Therefore, it has been proposed to form a light emitting element having layered structure arranged in the order of an auxiliary electrode, an insulating layer, an anode, an organic functional layer comprising a light emission layer, and a cathode on a substrate, and the anode is formed to have a smaller surface area than the cathode (Japanese Patent Kokai No. 2002-343578). With this arrangement of the light emitting element, the quantity of holes injected from the anode into the light emission layer increases when voltage is applied between the auxiliary electrode and the cathode in the same direction as the direction of voltage applied between the anode and the cathode.

The light emission luminosity of the light emitting element having such configuration is controlled by regulating the injection of holes, and material having low carrier density and high resistivity is used in the hole injection layer so as to increase the ON/OFF ratio. It is known that the holes are not liable to move in the spreading direction of the hole injection layer, and consequently, luminosity is high in a region where the anode and the cathode are closest to each other, and the luminosity declines as the distance from the anode increases. In other words, it has been found that a light emitting element having the above-described structure has a problem in that holes are injected in a concentrated fashion at the perimeter edge of the anode, and hence unevenness of light emission occurs in a pixel where the light emitting element is formed. Furthermore, it has been found that the light emitting element has a problem in that a region where holes are injected in a concentrated fashion suffers rapid degradation of the light emission layer and hence the element has a short lifespan.

### DISCLOSURE OF THE INVENTION

It is an object of the present invention to provide means for resolving various problems of which the aforementioned problems are shown by way of example.

The light emitting element according to a first aspect of the present invention comprises: an auxiliary electrode provided on a substrate; an insulating layer provided on the auxiliary electrode; a first electrode supported by the insulating layer; a carrier injection layer made of an organic conductive material having carrier injecting property, and making contact with the first electrode; a light emission layer supported by the carrier injection layer; and a second electrode supported by the light emission layer; wherein a carrier dispersion layer having lower resistance than the carrier injection layer is provided between the carrier injection layer and the light emission layer.

The display apparatus according to a second aspect of the present invention has a plurality of light-emitting sections arranged in a matrix pattern, and each of the light-emitting sections comprises: an auxiliary electrode provided on a substrate; an insulating layer provided on the auxiliary electrode; a first electrode supported by the insulating layer; a carrier injection layer made of an organic conductive material having carrier injecting property, and making contact with the first electrode; a light emission layer supported by the carrier injection layer; and a second electrode supported by the light emission layer; and wherein a carrier dispersion layer having lower resistance than the carrier injection layer is provided between the carrier injection layer and the light emission layer.

### BRIEF DESCRIPTION OF THE DRAWINGS

FIG. 1 is a partial cross-sectional view of an organic EL element according to the present invention;

FIG. 2 is a partial cross-sectional view of a modification of an organic EL element according to the present invention;

FIG. 3 is a partial cross-sectional view of a modification of an organic EL element according to the present invention;

FIG. 4 is a partial cross-sectional view of a modification of an organic EL element according to the present invention;

FIG. 5 is a partial plan view of an organic EL element according to the present invention;

FIG. 6 is an equivalent circuit diagram showing a sub-pixel light-emitting section of an organic EL element according to the present invention;

FIG. 7 is a partial cross-sectional view of a modification of an organic EL element according to the present invention; and

FIG. 8 is a partial cross-sectional view of a modification of an organic EL element according to the present invention.

### EMBODIMENTS FOR CARRING OUT THE INVENTION

As an example, an organic EL element of a light emitting element according to the present invention will be hereinafter described in detail with reference to the accompanying drawings.

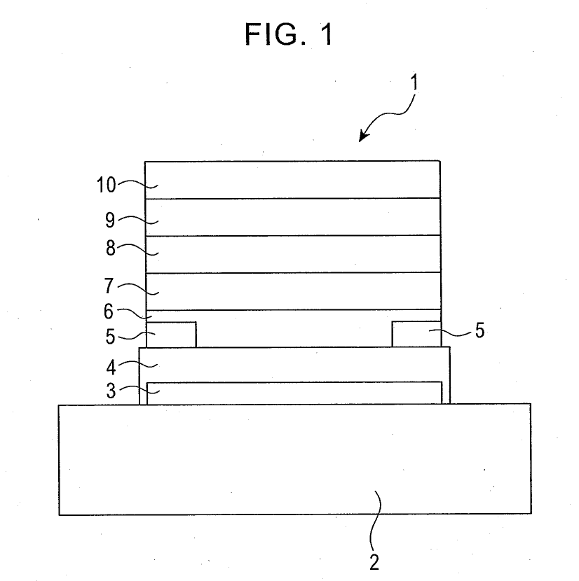

As shown in FIG. 1, an organic EL element 1 comprises an auxiliary electrode 3 provided on a substrate 2. Material of the substrate 2 is not limited to a semi-transparent material such as glass, quartz, and a plastic material such as polystyrene. The substrate 2 may be made of, but not limited to, an opaque material such as silicon and aluminum, a thermosetting resin such as phenol resin, and a thermoplastic resin such as polycarbonate or the like.

An insulating layer 4 is provided on the auxiliary electrode 3. The insulating layer 4 can be made of various insulating materials, of which SiO₂ and Si₃N₄ are typical examples. An inorganic oxide film having a high dielectric constant is especially desirable for the insulating layer 4. Examples of the inorganic oxide are silicon oxide, aluminum oxide, tantalum oxide, titanium oxide, tin oxide, vanadium oxide, barium strontium titanate, barium zirconate titanate, lead zirconate titanate, lead lanthanum titanate, strontium titanate, barium titanate, barium magnesium fluoride, bismuth titanate, strontium bismuth titanate, strontium bismuth tantalate, bismuth tantalate niobate, yttrium trioxide, and the like. Of these, preferable compounds are silicon oxide, aluminum oxide, tantalum oxide and titanium oxide. An inorganic nitride compound such as silicon nitride, aluminum nitride, or the like may be also preferably used. Furthermore, the organic compound film may be used which includes copolymer containing photo-curable resin such as polyimide, polyamide, polyester, polyacrylate, photo radical polymerization system and photo cationic polymerization system, acrylonitrile component, polyvinyl phenol, polyvinyl alcohol, novolac resin, and phosphazene compound containing cyanoethyl pullulan, polymer body, an elastomer body or the like.

An anode 5 is provided on the insulating layer 4, and the anode 5 serves as a first electrode. The anode 5 has a smaller surface area than the cathode 10 which will be described later. Specifically, a surface area of the anode 5 facing the cathode 10 is smaller than a surface area of the cathode 10 facing the anode 5. The anode 5 may be formed to have a comb shape, a blind shape or a lattice shape. As shown in FIG. 1, for example, the anode 5 may be formed to have a comb-shape having two teeth.

The anode 5 is in contact with a hole injection layer 6 made of an organic semiconducting material having carrier-injecting properties. The hole injection layer 6 has a function to facilitate injection of holes from the anode 5. Material used for the hole injection layer 6 may be porphyrin derivative as typified by copper phthalocyanine (CuPc), polyacene as typified by petacene, or aryl amine polymer called starburst amine as typified by m-TDATA. Furthermore, polymer material such as poly(3-hexyl-thiophene) (P3HT) may be used for the hole injection layer 6. Moreover, the carrier injection layer may be a mixed layer or a laminated layer combining these materials. The hole injection layer can be formed by means of a film deposition method such as vacuum vapor deposition.

An upper part of the hole injection layer 6 supports a carrier dispersion layer 7. The carrier dispersion layer 7 has lower resistance than the hole injection layer 6, and it has a function to diffuse the carriers injected from the anode 5 in a spreading direction of the hole injection layer 6. The carrier dispersion layer 7 is formed to have higher conductivity by mixing a carrier transporting material (acceptor molecules) such as tetracyanoethylene (TCNE) and tetrafluoride-tetracyano-quinodimethane (F4-TCNQ), into an organic semiconductor material such as copper phthalocyanine (CuPc), zinc phthalocyanine (ZnPc), and a triphenylamine derivative. With regard to the mixing ratio, it is preferable that the acceptor molecules are mixed in a ratio of 5 to 50% by weight. When polymer system is utilized, polymer material such as polyaniline (PANI), a polythiophene derivative (PEDOT) may be used.

Density of the added material (dopant) need not be necessarily uniform throughout the carrier dispersion layer, and the density may vary within the carrier dispersion layer. For example, the density of the dopant within the carrier dispersion layer may be increased as the distance increases from the hole injection layer. Change in density of the dopant improves diffusion of the carrier within the carrier dispersion layer, thereby making it possible to uniformly inject the carriers into the light emission layer.

The carrier dispersion layer 7 may be made of a metal film or a metal oxide film. Material used for the metal film may be selected from Au, Pt, Pd, Ag, Al, Mg, or the like. A metal oxide such as V₂O₆ may be used for the metal oxide film. The thickness of the metal film and the metal oxide film may be preferably 100 nm or less, and more preferably, approximately 1 to 30 nm in view of the transmission efficiency of light passing through the thin film.

It is preferable that the carrier dispersion layer 7 is formed so as not to make direct contact with any of the auxiliary electrode 3, the anode 5 and the cathode (described below).

It is furthermore preferable that the carrier dispersion layer 7 has a surface area that is larger than a carrier injection region defined by the anode 5 serving as the first electrode. It should be noted that the carrier injection region represents a region enclosed by the anode in the light emitting element when the anode have a comb shape, a blind shape, or a lattice shape. For example, as shown in FIG. 1, if the anode 5 has a comb shape consisting of two teeth, then the carrier injection region represents an area enclosed by the comb teeth.

A hole transportation layer 8 is formed on the carrier dispersion layer 7. The hole transportation layer 8 has a function to stably transport holes supplied from the carrier dispersion layer 7. Material used for the hole transportation layer 8 may be a triphenyl diamine derivative, a stearyl amine derivative, an amine derivative having an aromatic condensed ring, and a carbazole derivative. The hole transportation layer 8 may be made of polymer such as polyvinyl carbazole and a derivative thereof, and polyolefin. Two or more of these compounds may be used in combination. Moreover, it is generally preferable that the hole transportation layer 8 is made of an organic semiconductor material having higher ionization potential Ip than the hole injection layer 6.

A light emission layer 9 is provided on the hole transportation layer 8. In other words, the light emission layer 9 is supported by the hole injection layer 6 via the hole transportation layer 8. The light emission layer 9 contains a fluorescent material or a phosphorescent material, which is a compound having light-emitting functions. Such fluorescent material may be selected from compounds such as quinacridone, rubrene, and stearyl dye which are disclosed in Japanese Patent Kokai No. 63-264692. The phosphorescent material may be an organic iridium complex, an organic platinum complex, or the like, which are shown in Appl. Phys. Lett., Vol. 75, p. 4, 1999.

A cathode 10 is provided on the light emission layer 9, and this cathode 10 serves as a second electrode.

The cathode 10, the anode 5, and the auxiliary electrode 3 may be formed of metal such as Ti, Al, Li:Al, Cu, Ni, Ag, Mg:Ag, Au, Pt, Pd, Ir, Cr, Mo, W or Ta, or alloys thereof. Alternatively, a conductive polymer such as polyaniline, or PEDT:PSS may be used. Alternatively, material mainly including a transparent conducting oxide thin film such as indium tin oxide (ITO), indium zinc oxide (IZO), indium oxide (In₂O₃), zinc oxide (ZnO), or tin oxide (SnO₂) may be used, although not limited thereto. Furthermore, it is preferable that the thickness of the electrodes is approximately 30 to 500 nm. A thickness ranging approximately 50 to 300 nm is particularly suitable for the cathode 10 and the auxiliary electrode 3. A thickness ranging approximately 10 to 200 nm is suitable for the anode 5. It is preferable that the. anode 5 is made of metal having higher work function such as Au, Pt or Pd which readily injects holes into the hole injection layer 6. A thickness ranging approximately 30 to 200 nm is particularly suitable for the cathode 10. These electrodes are preferably manufactured by vacuum vapor deposition or sputtering.

In an organic EL element 1 having the above-described configuration, the light emission layer 9 emits light when voltage is applied between the auxiliary electrode 3 and the cathode 10 in the same direction as the voltage applied between the anode 5 and the cathode 10.

In other words, when voltage is applied between the anode 5 and the cathode 10, and voltage is also applied between the auxiliary electrode 3 and the cathode 10 in the same direction as the direction of the voltage applied between the anode 5 and the cathode 10, then holes are injected from the anode 5 into the hole injection layer 6 and transported to the light emission layer 9, whereas electrons are injected from the cathode 10 to the light emission layer 9.

In this instance,. the holes injected to the hole injection layer 6 do not disperse in the lateral direction, i.e., the spreading direction of the hole injection layer 6, but rather they move towards the cathode. When the holes arrive at the carrier dispersion layer 7, they are dispersed in the lateral direction, i.e., the spreading direction of the carrier dispersion layer 7, and hence the density of holes in the light-emitting region of the pixel becomes uniform. Consequently, the luminosity in the light-emitting region becomes uniform and unevenness of light emission are not liable to occur.

Specifically, provision of a carrier dispersion layer having lower resistivity than the hole injection layer between the hole injection layer and the light emission layer increases travel distance of the holes in a direction parallel to the light emission surface of the pixel, and consequently, unevenness of light emission can be reduced. Therefore, even when an organic EL element having relatively larger pixel is manufactured, it is possible to obtain good visual characteristics without sensing unevenness of the light emission.

Furthermore, improvement of the unevenness of light emission within each pixel provides uniform light emission of the light emission layer in the light emission region, thereby improving the light emission lifespan of the organic EL element.

Moreover, the organic EL element 1 having the above-described configuration is a passive element and has a feature that it can be formed without greatly changing the manufacturing process of the organic EL element.

What is more, use of this light-emitting element makes it possible to reduce the number of devices arranged in each pixel for performing active matrix driving, and to achieve lower cost, reduced power consumption and longer lifespan as compared with an organic EL display apparatus using polysilicon, or the like.

The direction of voltage applied between the electrodes is not limited to the direction described above. For example, the embodiment may be achieved by connecting the anode to ground, applying a negative voltage to the cathode, and applying a negative voltage to the auxiliary electrode. In this case, the direction of the voltage applied between the anode and the cathode is opposite from the direction of the voltage applied between the auxiliary electrode 3 and the cathode 10.

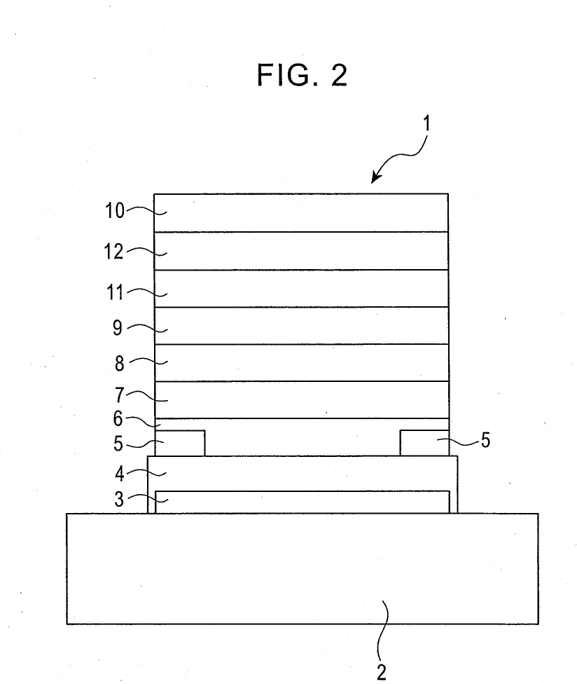

Even though the organic EL element according to the embodiment has been described with reference to FIG. 1 on the basis of the layered structure arranged in the order of an auxiliary electrode, insulating layer, anode, hole injection layer, carrier dispersion layer, hole transportation layer, light emission layer, and cathode. The organic EL element is not limited thereto. The organic EL element may be arbitrarily provided with an electron injection layer, an electron transportation layer, or a combination thereof between the light emission layer and the cathode. For example, as shown in FIG. 2, an electrode transportation layer 11 and an electron injection layer 12 may be provided between the light emission layer 9 and the cathode 10.

Material of the electron injection layer 12 and/or the electron transportation layer 11 may be a quinoline derivative such as an organic metal complex comprising an 8-quinolinol such as tris(8-quinolinolate) aluminum (Alq₃) or a derivative thereof as a ligand, an oxadiazole derivative, a perylene derivative, a pyridine derivative, a pyrimidine derivative, a quinoxaline derivative, a diphenyl quinone derivative, a nitro-substituted fluorene derivative, or the like. The electron injection layer 12 and/or the electron transportation layer 11 may be combined with the light emission layer 9, and in this case, it is preferable to use tris(8-quinolinolate) aluminum. When an electron injection layer 12 and an electron transportation layer 11 are both manufactured, it is preferable that they are deposited in such a manner that the compound having higher electron affinity is adjacently disposed to the cathode 10.

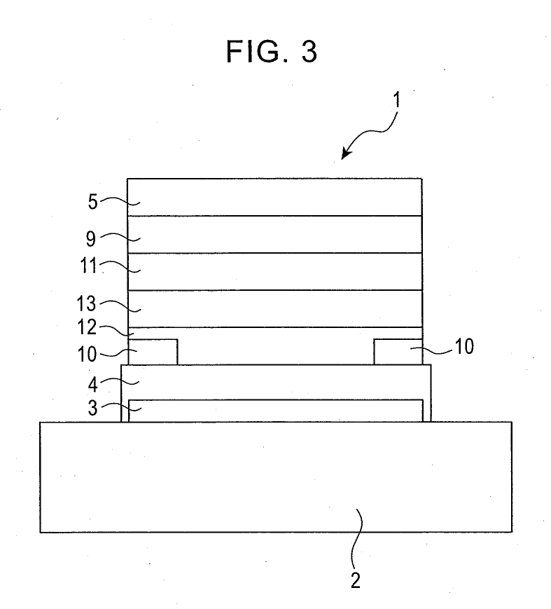

The embodiment has been described on the basis of the structure in which the first electrode represents an anode and the second electrode represents a cathode, however order of the layer above the insulating layer may be reversed. Specifically, the first electrode may be a cathode and the second electrode may be an anode. For example, as shown in FIG. 3, the organic EL element 1 may have a layered structure arranged in the order of an auxiliary electrode 3, insulating layer 4, cathode 10, electron injection layer 12, carrier dispersion layer 13, electron transportation layer 11, light emission layer 9, and anode 5.

In this instance, the carrier dispersion layer 13 is made to have higher conductivity by mixing a carrier transporting material (donor material) such as cesium (Cs) as a dopant into an organic semiconductor material such as bathocuproine (BCP).

Although not shown in the drawings, a hole blocking layer and an electron blocking layer may be arbitrarily provided between the first electrode and the second electrode.

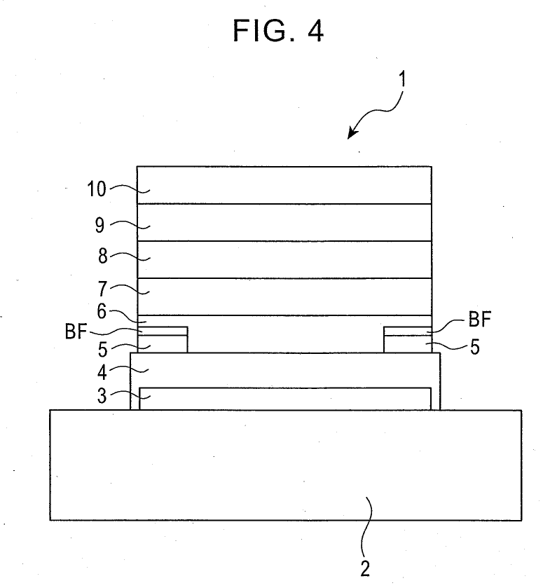

The organic EL element may include a carrier restricting layer between the carrier injection layer and the anode. For example, as shown in FIG. 4, the organic EL element 1 may be provided with a carrier restricting layer BF which is arranged between the hole injection layer 6 and the anode 5 so as to be sandwiched between the anode 5 and the cathode 10. The carrier restricting layer BF has a function to block carrier movement from the anode 5 to the hole injection layer 6. Provision of this carrier restricting layer BF suppresses flow of electric current via the carrier restricting layer BF.

Material of the carrier restricting layer BF is selected on the basis of the ionization potential conditions, i.e., a work function (or ionization potential) value between a work function of the contacting electrode and an ionization potential of the hole injection layer. Specifically, it is preferable that material of the carrier restricting layer BF may have a work function that is significantly different from that of the material used for the anode 5, or alternatively, it is preferable that material used for the insulating layer is used for the carrier restricting layer BF. This is because, in order to block carrier injection, a larger energy barrier is preferable.

For example, it is preferable for the carrier restricting layer BF to use a metal having a low work function such as Al, Mg, Ag, Ta or Cr which does not readily inject holes into the hole injection layer 6. A suitable range for the combined thickness of the anode 5 and the carrier restricting layer BF is approximately 30 to 200 nm.

Provision of this carrier restricting layer BF defines a passage of carriers injected into the hole injection layer 6. In the case of the configuration shown in FIG. 4 in which the carrier restricting layer BF is sandwiched between the anode 5 and the cathode 10, the carriers (holes) will be injected from the region that is not covered with the carrier restricting layer BF, i.e., a side portion of the anode 5. In this case, since the side portion of the anode 5 is completely covered with the hole injection layer 6, carrier injection efficiency is improved. Provision of the carrier restricting layer improves performance of the organic EL element, which may be for example a good ON/OFF ratio.

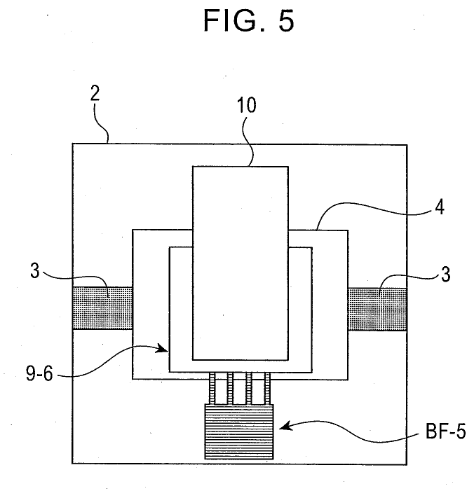

The anode 5 serving as the first electrode has a smaller surface area than the cathode 10 serving as the second electrode, and the anode 5 defines a pattern for the carriers passing through the hole injection layer 6. For example, as shown in FIG. 5, the anode 5 serving as the first electrode and the carrier restricting layer BF may have a comb shape or blind shape, and have surface areas which are smaller than the cathode 10 serving as the second electrode. Alternatively, the shape of the anode 5 and the carrier restricting layer BF may be a lattice shape. When at least one of the anode 5 and the carrier restricting layer BF is formed to have a lattice shape, a comb shape or a blind shape, then the anode 5 can be made to have a smaller surface area than the cathode 10 and a pattern can be defined for the carriers passing through the hole injection layer 6.

The organic EL elements of the above-described embodiment can apply to pixels of a display apparatus. Specifically, when at least one organic transistor, a necessary element such as a capacitor, pixel electrodes, and the like are formed on a common substrate, then it is possible to achieve an active drive type display apparatus according to the present invention. One example of the structure applied to a display apparatus will be described below.

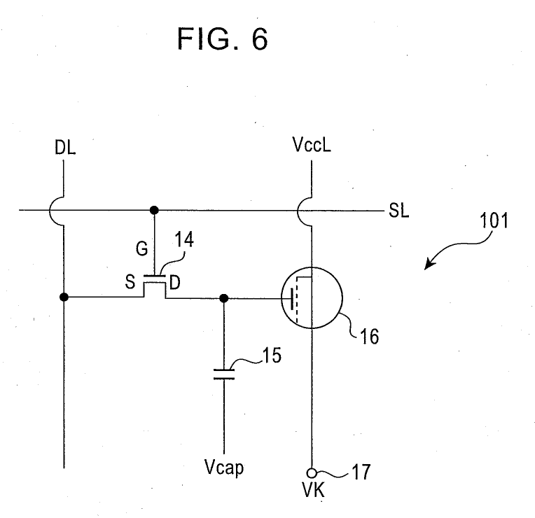

FIG. 6 shows an equivalent circuit diagram of a light-emitting section of a sub-pixel in an organic EL display panel. Each light-emitting section 101 formed on the substrate includes a switching organic TFT element 14 of a selection transistor, a capacitor 15 for holding the data voltage, and an organic EL element 16. Arrangement of this configuration in the vicinity of each of intersections of the scanning lines SL with the power supply lines VccL and the data lines DL achieves the light-emitting sections of the pixels. The embodiment provides an effect to omit a drive transistor, but the present invention may also be applied to an organic EL display panel having two or more driving organic TFT elements.

The gate electrode G of the switching organic TFT element 14 is connected to a scanning line SL to which an address signal is supplied, and the source electrode S of the switching organic TFT element 14 is connected to a data line DL to which a data signal is supplied. The drain electrode D of the switching organic TFT element 14 is connected to the auxiliary electrode 3 of the organic EL element 16 and to one terminal of the capacitor 15. The anode 5 of the organic EL element 16 is connected to the power supply line VccL. The other end of the capacitor 15 is connected to a capacitor line Vcap. The cathode 10 of the organic EL element 16 is connected to a common electrode 17. The power supply line VccL and the common electrode 17 are respectively connected to voltage sources (not shown) which supply power thereto.

A plurality of the light-emitting sections 101 each having this configuration are arranged in a matrix pattern to form an organic EL display panel of an active matrix display type. The organic EL elements of the above-described embodiment can also apply to a panel of a passive matrix display type, in which TFT elements or the like are arranged around the panel screen.

### Embodiment 1

A light-emitting element having the configuration shown in FIG. 1 was manufactured.

(1) Formation of Auxiliary Electrode 3

After forming ITO onto a non-alkali glass substrate To have a thickness of 100 nm by sputtering, a photoresist was applied by spin coating. The photoresist was patterned by exposure using an optical mask and development, and then the ITO film was removed in the portion having no photoresist pattern by milling. Finally, the photoresist was dissolved using a removing solution.

(2) Formation of Insulating Layer 4

An insulating layer was formed to have a thickness of 300 nm by spin coating using propylene glycol monomethyl ether acetate (PGMEA) solution containing 8 wt % of polyvinyl phenol polymer. The polymer film deposited on the end sections of the auxiliary electrode was then wiped away with cotton containing PGMEA, and baking was carried out for 180 minutes at 200° C. using a hot plate.

(3) Formation of Anode 5

The anode was formed by depositing gold to have a thickness of 50 nm by vacuum vapor deposition using a metal mask. The deposition rate of gold was 0.1 m/s. Subsequently, a 100 nm thickness of SiO₂ was deposited by vacuum vapor deposition with an electron beam using the same mask. The film deposition rate of SiO₂ was 0.4 nm/s.

(4) Formation of Hole Injection Layer 6

The hole injection layer was formed by depositing petacene to have a thickness of 50 nm. In this instance, the deposition rate of petacene was 0.1 nm/s.

(5) Formation of Carrier Dispersion Layer 7

The carrier dispersion layer was formed to have a vapor co-deposition film with a thickness of 100 nm in which copper phthalocyanine includes 10 wt % of F4-TCNQ.

(6) Formation of Hole Ttransportation Layer 8

The hole transportation layer was formed by depositing a-NPD to have a thickness of 50 nm.

(7) Formation of Light Emission Layer 9

The light emission layer was formed by depositing tris(8-quinolinolate) aluminum to have a thickness of 60 nm by vacuum vapor deposition.

(8) Formation of Cathode 10

The cathode was formed to have a vapor co-deposition film of magnesium and silver to with a thickness of 100 nm by vacuum vapor deposition. The deposition rate of magnesium was 1 nm/s, and the deposition rate of silver was 0.1 nm/s.

All of the steps from (3) to (8) were performed using one consecutive train of vacuum apparatuses. FIG. 5 shows a plan view of the light-emitting element according to the Embodiment 1 viewed from above the substrate side. As shown in FIG. 5, the electrodes beside the hole injection layer, i.e., the anode 5 and the carrier restricting layer BF in this case, are formed to have a comb shape or blind shape, but they may also be formed to have a lattice shape. Furthermore, if at least one of the anode 5 and the carrier restricting layer BF is formed to have a lattice shape, a comb shape or a blind shape, then the anode 5 beside the hole injection layer can be formed to have a smaller surface than the cathode 10 and a pattern for the carriers passing through the hole injection layer 6 can be defined.

### Embodiment 2

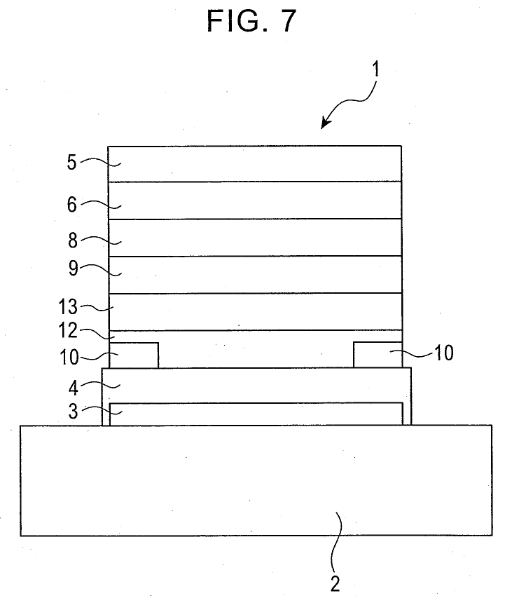

An organic EL element having the configuration shown in FIG. 7 was manufactured by the following method.

(1) Formation of Auxiliary Electrode 3

After forming ITO onto a non-alkali glass substrate to have a thickness of 100 nm by sputtering, the ITO was patterned in a similar fashion to the Embodiment 1.

(2) Formation of Insulating Layer 4

The insulating layer was formed by depositing SiO₂ to have a thickness of 300 nm by sputtering. In this instance, in order not to form the insulating layer on a portion of the auxiliary electrode, a deposition area was limited by using a metal mask.

(3) Formation of Anode 10

The anode was formed to have a vapor co-deposition film of magnesium and silver with a thickness of 20 nm by vacuum vapor deposition with a ratio of 10:1. In this instance, the deposition rate of magnesium was 1 nm/s, and the deposition rate of silver was 0.1 nm/s. Thereafter, platinum was vapor deposited to have a thickness of 20 nm using the same mask.

(4) Formation of Electron Injection Layer 12

The electron injection layer was formed to have a carbon film of Fullerene C₆₀ by vacuum vapor deposition.

(5) Formation of Carrier Dispersion Layer 13

The carrier dispersion layer was formed by simultaneous vapor deposition of bathocuproine (BCP) and cesium (Cs). The density of the cesium in the carrier dispersion layer was 5 wt %.

(6) Formation of Light Emission Layer 9

The light emission layer was formed to have a vapor co-deposition film of tris(8-quinolinlate) aluminum (Alq3) and coumarin (C545T) with a thickness of 40 nm by vacuum vapor deposition. The density of the coumarin in the light emission layer was 3 wt %. The deposition rate of Alq3 was 0.3 nm/s.

(7) Formation of Hole Transportation Layer 8

The hole transportation layer was formed by depositing α-NPD to have a thickness of 50 nm by vacuum vapor deposition.

(8) Formation of Hole Injection Layer 6

The hole injection layer was formed by depositing CuPc to have a thickness of 50 nm by vacuum vapor deposition.

(9) Formation of Anode 5

The anode was formed by depositing gold to have a thickness of 30 nm by sputtering. In this instance, the deposition rate of gold was 1 nm/s.

All of the steps from (3) to (9) were carried out in one consecutive train of vacuum apparatuses.

(Example of Driving)

An organic EL element made by the procedure shown in the Embodiment 1 described above (Embodiment 1) and an organic EL element made by the same procedure as the Embodiment 1 except for the forming step of a carrier dispersion layer (Comparison Example 1) were compared with each other in terms of the light emission state of the light-emitting section. The light-emitting section of the organic EL element according to the Embodiment 1, in which a carrier dispersion layer is formed, provides uniform luminosity throughout the light emission region and unevenness of light emission were not observed. On the other hand, the organic EL element according to the Comparison Example 1, in which a carrier dispersion layer is not formed, provides higher luminosity in the vicinity of the edge sections of the anode and the luminosity became lower as the distance increases from the anode, thus producing unevenness of light emission.

### Other Embodiments

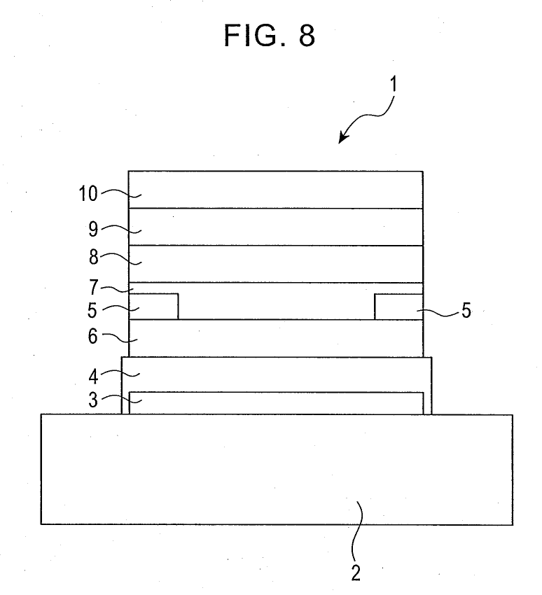

In the Embodiment 1 described above, the organic EL element has a layered structure arranged in the order of auxiliary electrode, insulating layer, anode, hole injection layer, carrier dispersion layer, hole transportation layer, light emission layer, and cathode, which is a so-called bottom contact structure, but the configuration is not limited thereto. Alternatively, as shown in FIG. 8, the film deposition sequence may be changed between the anode 5 and the hole injection layer 6 so that a hole injection layer 6, anode 5, and carrier dispersion layer 7 are formed in this order on the insulating layer 4 (Embodiment 3). Specifically, the organic EL element may have such configuration that the anode 5 is inserted between the hole injection layer 6 and the carrier dispersion layer 7 and that the anode 5 makes direct contact with the hole injection layer 6 and the carrier dispersion layer 7, which is a so-called top-contact structure. In other words, configuration of the organic EL element is not limited to that shown in the Embodiment 1, provided that the first electrode is supported by the insulating layer, and that a carrier injection layer is sandwiched between the insulating layer and the first electrode.

Similarly, in the Embodiment 2 described above, the organic EL element has a layered structure arranged in the order of an auxiliary electrode, insulating layer, cathode, electron injection layer, carrier dispersion layer, light emission layer, hole transportation layer, hole injection layer, and anode, but the configuration is not limited thereto. Alternatively, the film deposition sequence may be changed between the cathode and the electron injection layer so that an electron injection layer, cathode, and carrier dispersion layer are provided in this order on the insulating layer (Embodiment 4). Specifically, the organic EL element may have such configuration that the cathode is inserted between the electron injection layer and the carrier dispersion layer and that the cathode makes direct contact with the electron injection layer and the carrier dispersion layer. In this configuration, it is preferable that a carrier restricting layer BF is provided between the carrier dispersion layer and the anode (or cathode) so that the carrier dispersion layer and the anode do not make direct contact with each other.

As described above, the organic EL element according to the Embodiment 3 has the layered structure arranged in the order of an auxiliary electrode, insulating layer, hole injection layer, anode, carrier dispersion layer, hole transportation layer, light emission layer, and cathode, whereas the organic EL element according to the Embodiment 4 has a layered structure arranged in the order of an auxiliary electrode, insulating layer, electron injection layer, cathode, carrier dispersion layer, light emission layer, hole transportation layer, hole injection layer, and anode, however a hole blocking layer, an electron transportation layer, an electron injection layer, or the like may be arbitrarily inserted thereto.

This application is based on a Japanese Patent Application No. 2005-300595 which is herein incorporated by reference.

1-19. (canceled)

20. A light-emitting element, comprising:
an auxiliary electrode provided on a substrate;
an insulating layer provided on said auxiliary electrode;
an anode supported by said insulating layer;
a hole injection layer made of an organic conductive material having carrier injecting property, and making contact with said anode;
a light emission layer supported by said hole injection layer;
a cathode supported by said light emission layer; and
a hole dispersion layer between said hole injection layer and said light emission layer, said hole dispersion layer having lower resistance than said hole injection layer,
wherein a hole restricting layer that is sandwiched between said anode and said cathode is inserted between said anode and said hole injection layer, and said hole restricting layer contacts said anode and said hole injection layer, said hole restricting layer being made of a metal selected from a group of Al, Mg, Ag, TA and Cr.

21. The light-emitting element according to claim 20, wherein said hole dispersion layer is an organic thin film doped with carrier transporting material.

22. The light-emitting element according to claim 20, wherein said hole dispersion layer includes either a metal film or a metal oxide film.

23. The light-emitting element according to claim 22, wherein said metal film or said metal oxide film has a thickness of 100 nm or less.

24. The light-emitting element according to claim 20, wherein said anode has a lattice shape, a comb shape or a blind shape.

25. The light-emitting element according to claim 24, wherein said hole dispersion layer has a greater surface area than a carrier injection region defined by said anode.

26. The light-emitting element according to claim 20, wherein said hole injection layer is sandwiched between said insulating layer and said anode.

27. A display apparatus having a plurality of light-emitting sections arranged in a matrix pattern, and each of said light-emitting sections comprising:
an auxiliary electrode provided on a substrate;
an insulating layer provided on said auxiliary electrode;
an anode supported by said insulating layer;
a hole injection layer made of an organic conductive material having carrier injecting property, and making contact with said anode;
a light emission layer supported by said hole injection layer;
a cathode supported by said light emission layer, and
a hole dispersion layer between said hole injection layer and said light emission layer, said hole dispersion layer having lower resistance than said hole injection layer,
wherein a hole restricting layer that is sandwiched between said anode and said cathode is inserted between said anode and said hole injection layer, and said hole restricting layer contacts said anode and said hole injection layer, said hole restricting layer being made of a metal selected from a group of Al, Mg, Ag, TA and Cr.

28. The display apparatus according to claim 27 further comprising a switching element electrically connected to said auxiliary electrode in each of said light-emitting sections, wires for supplying electrical power to said anodes and cathodes, and wires for supplying on/off voltage information to said switching elements.

29. The display apparatus according to claim 27, wherein said hole dispersion layer is an organic thin film doped with carrier transporting material.

30. The display apparatus according to claim 27, wherein said hole dispersion layer includes either a metal film or a metal oxide film.

31. The display apparatus according to claim 30, wherein said metal film or said metal oxide film has a thickness of 100 nm or less.

32. The display apparatus according to claim 27, wherein said anode has a lattice shape, a comb shape or a blind shape.

33. The display apparatus according to claim 32, wherein said hole dispersion layer has a greater surface area than a carrier injection region defined by said anode.

34. The display apparatus according to claim 27, wherein said hole injection layer is sandwiched between said insulating layer and said anode.

35. A light-emitting element, comprising:
an auxiliary electrode provided on a substrate;
an insulating layer provided on said auxiliary electrode;
a cathode supported by said insulating layer;
an electron injection layer made of an organic conductive material, and making contact with said cathode;
a light emission layer supported by said electron injection layer;
an anode supported by said light emission layer; and
a carrier dispersion layer between said electron injection layer and said light emission layer,
wherein a carrier restricting layer that is sandwiched between said anode and said cathode is inserted between said cathode and said electron injection layer, and said carrier restricting layer contacts said cathode and said carrier injection layer.

36. A display apparatus having a plurality of light-emitting sections arranged in a matrix pattern, and each of said light-emitting sections comprising:
an auxiliary electrode provided on a substrate;
an insulating layer provided on said auxiliary electrode;
a cathode supported by said insulating layer;
an electron injection layer made of an organic conductive material having carrier injecting property, and making contact with said cathode;
a light emission layer supported by said electron injection layer;
an anode supported by said light emission layer, and
a carrier dispersion layer between said electron injection layer and said light emission layer,
wherein a carrier restricting layer that is sandwiched between said anode and said cathode is inserted between said cathode and said electron injection layer, and said carrier restricting layer contacts said cathode and said electron injection layer.
